(19) United States
(12) Patent Application Publication
(10) Pub. No.: US 2018/0323765 A1
(43) Pub. Date: Nov. 8, 2018

(54) COMPACT SCALABLE ON-CHIP INDUCTOR-CAPACITOR (LC) RESONATOR USING CONFORMALLY DISTRIBUTED CAPACITORS

(71) Applicant: QUALCOMM Incorporated, San Diego, CA (US)

(72) Inventors: Miena Armanious, Boulder, CO (US); Lan Nan, San Diego, CA (US); Mina Iskander, San Diego, CA (US)

(21) Appl. No.: 15/585,810

(22) Filed: May 3, 2017

(51) Int. Cl. H03H 7/01; H03H 1/00; H03H 3/00

(52) U.S. Cl. CPC H03H 7/0115; H03H 2001/0021; H03H 3/00; H03H 1/00

(57) ABSTRACT

Aspects of the disclosure are directed to an inductor-capacitor (LC) resonator. In accordance with one aspect, the LC resonator architecture includes a lower metal plate, the lower metal plate is of an open configuration; an upper metal plate, the upper metal plate is stacked vertically above the lower metal plate and is vertically aligned to the lower metal plate; a first ultra thick metal (UTM) plate, the first UTM plate is stacked vertically above the upper metal plate and is vertically aligned to both the upper metal plate and the lower metal plate; and an electrical coupling to couple the first UTM plate to the upper metal plate, wherein a current on the first UTM plate flows through to the upper metal plate through the electrical coupling, the current flows in a direction on the first UTM plate and in the same direction on the upper metal plate.

### TECHNICAL FIELD

This disclosure relates generally to the field of inductor-capacitor (LC) resonator, and, in particular, to a scalable on-chip inductor-capacitor (LC) resonator using conformally distributed capacitors.

### BACKGROUND

Shunt and series resonators comprised of inductors (L) and capacitors (C) (i.e., LC resonators) are two main constituents in electronic systems. Conventional designs of the LC resonator may cause an induced image current. The induced image current which is caused by a source in one part of a circuit may be an undesirable current in another part of the circuit. Additionally, conventional designs of the LC resonator with overlapping areas may cause an image current on the top metal layer of a capacitor to flow in the opposite direction as the inductor current. As a consequence, the total magnetic current may be significantly reduced and the inductance value may also be reduced. To address the reduction of the total magnetic current and the reduction of the inductance value, conventional designs of the LC resonator may implement non-overlapping areas for the inductor and capacitor. However, such conventional designs have resulted in undesired large size of the LC resonator. Hence, issues relating to size, reduction of total magnetic current and reduction of inductance value need to be addressed to optimize an inductor-capacitor (LC) resonator.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides an inductor-capacitor resonator architecture. Accordingly, an inductor-capacitor (LC) resonator architecture, including a lower metal plate, wherein the lower metal plate is of an open configuration; an upper metal plate, wherein the upper metal plate is stacked vertically above the lower metal plate and is vertically aligned to the lower metal plate; a first ultra thick metal (UTM) plate, wherein the first UTM plate is stacked vertically above the upper metal plate and is vertically aligned to both the upper metal plate and the lower metal plate; and an electrical coupling to couple the first UTM plate to the upper metal plate, wherein a current on the first UTM plate flows through to the upper metal plate through the electrical coupling, the current flows in a direction on the first UTM plate and in the same direction on the upper metal plate. In one example, the inductor-capacitor (LC) resonator architecture further includes a second ultra thick metal (UTM) plate, the second UTM plate electrically coupled to the upper metal plate.The inductor-capacitor (LC) resonator architecture may also include a circuit input terminal, wherein the circuit input terminal is electrically coupled to the first UTM plate. The inductor-capacitor (LC) resonator architecture may further include a circuit output terminal, wherein the circuit output terminal is electrically coupled to one or more of the following: the second UTM plate or the upper metal plate. In one example, the lower metal plate has a first planar shape and the open configuration is a first center hole on the first planar shape. In one example, the upper metal plate has a second planar shape and the second planar shape has a second center hole. In one example, the first UTM plate has a third planar shape and the third planar shape has a third center hole. In one example, the first center hole, the second center hole and the third center hole are of the same shape and are each vertically aligned to one another along an axis. The axis may be the y-axis as illustrated in FIG. 2. In one example, the electrical coupling is a via. In one example, the first UTM plate and the upper metal plate are constituents of an inductor, and the lower metal plate and the upper metal plate are constituents of a capacitor. In one example, the inductor and the capacitor are electrically coupled in series. In another example, the inductor and the capacitor are electrically coupled in parallel. In one example, the capacitor is either a metal oxide semiconductor (MOS) capacitor or a metal insulator metal (MIM) capacitor. In one example, the first ultra thick metal (UTM) plate includes a plurality of metal plates, the plurality of metal plates being constituents for at least two or more inductors. The at least two or more inductors may be electrically coupled in parallel or in series. In one example, the lower metal plate includes a plurality of discrete metal plates, the plurality of discrete metal plates being constituents for at least two or more capacitors. The at least two or more capacitors may be electrically coupled in parallel or in series.

Another aspect of the disclosure provides a method for implementing a scalable on-chip inductor-capacitor (LC) resonator using one or more conformally distributed capacitors including providing a lower metal plate, wherein the lower metal plate is of an open configuration; providing an upper metal plate, wherein the upper metal plate is stacked vertically above the lower metal plate and is vertically aligned to the lower metal plate; providing a first ultra thick metal (UTM) plate, wherein the first UTM plate is stacked vertically above the upper metal plate and is vertically aligned to both the upper metal plate and the lower metal plate; and placing an electrical coupling to couple the first UTM plate to the upper metal plate, wherein a current on the first UTM plate flows through to the upper metal plate through the electrical coupling, the current flows in a direction on the first UTM plate and in the same direction on the upper metal plate. In one example, the method further includes electrically coupling a second ultra thick metal (UTM) plate to the upper metal plate. In one example, the lower metal plate has a first planar shape and further comprising implementing a first center hole on the first planar shape. In one example, the upper metal plate has a second planar shape and further comprising implementing a second center hole on the second planar shape. In one example, the first UTM plate has a third planar shape and further comprising implementing a third center hole on the third planar shape. In one example, the method further includes vertically aligning the first center hole, the second center hole and the third center hole to each other along an axis.

Another aspect of the disclosure provides an apparatus for implementing a scalable on-chip inductor-capacitor (LC) resonator using one or more conformally distributed capacitors, the apparatus including: means for providing a lower metal plate, wherein the lower metal plate is of an open configuration; means for providing an upper metal plate, wherein the upper metal plate is stacked vertically above the lower metal plate and is vertically aligned to the lower metal plate; means for providing a first ultra thick metal (UTM) plate, wherein the first UTM plate is stacked vertically above the upper metal plate and is vertically aligned to both the upper metal plate and the lower metal plate; and means for placing an electrical coupling to couple the first UTM plate to the upper metal plate, wherein a current on the first UTM plate flows through to the upper metal plate through the electrical coupling, the current flows in a direction on the first UTM plate and in the same direction on the upper metal plate. In one example the apparatus further includes means for electrically coupling a second ultra thick metal (UTM) plate to the upper metal plate.

Another aspect of the disclosure provides a computer-readable medium storing computer executable code, operable on a device comprising at least one processor and at least one memory coupled to the at least one processor, wherein the at least one processor is configured to implement a scalable on-chip inductor-capacitor (LC) resonator using one or more conformally distributed capacitors, the computer executable code including: instructions for causing a computer to provide a lower metal plate, wherein the lower metal plate is of an open configuration; instructions for causing the computer to provide an upper metal plate, wherein the upper metal plate is stacked vertically above the lower metal plate and is vertically aligned to the lower metal plate; instructions for causing the computer to provide a first ultra thick metal (UTM) plate, wherein the first UTM plate is stacked vertically above the upper metal plate and is vertically aligned to both the upper metal plate and the lower metal plate; and instructions for causing the computer to place an electrical coupling to couple the first UTM plate to the upper metal plate, wherein a current on the first UTM plate flows through to the upper metal plate through the electrical coupling, the current flows in a direction on the first UTM plate and in the same direction on the upper metal plate. In one example, the computer-readable medium further includes instructions for causing the computer to electrically couple a second ultra thick metal (UTM) plate to the upper metal plate.

These and other aspects of the invention will become more fully understood upon a review of the detailed description, which follows. Other aspects, features, and embodiments of the present invention will become apparent to those of ordinary skill in the art, upon reviewing the following description of specific, exemplary embodiments of the present invention in conjunction with the accompanying figures. While features of the present invention may be discussed relative to certain embodiments and figures below, all embodiments of the present invention can include one or more of the advantageous features discussed herein. In other words, while one or more embodiments may be discussed as having certain advantageous features, one or more of such features may also be used in accordance with the various embodiments of the invention discussed herein. In similar fashion, while exemplary embodiments may be discussed below as device, system, or method embodiments it should be understood that such exemplary embodiments can be implemented in various devices, systems, and methods.

### BRIEF DESCRIPTION OF THE DRAWINGS

FIG. 1 illustrates a conventional inductor-capacitor (LC) resonator structure.

FIG. 2 illustrates an example inductor-capacitor (LC) resonator architecture in accordance with the present disclosure.

FIG. 3A illustrates an example design layout for implementing an inductor capacitor (LC) resonator in a silicon on insulator (SOI) technology.

FIG. 3B illustrates a perspective view of an example electromagnetic model (e.g., high frequency structural simulator (HFSS) modeling) of the example design layout of FIG. 3A.

FIG. 3C illustrates a side view of the example electromagnetic model of FIG. 3B.

FIG. 4A illustrates an example inductance graph for two configurations in accordance with an example LC resonator of the present disclosure.

FIG. 4B illustrates an example quality factor graph for two configurations in accordance with an example LC resonator of the present disclosure.

FIG. 5A illustrates an example inductance graph for two configurations of a conventional LC resonator in accordance with FIG. 1.

FIG. 5B illustrates an example quality factor graph for two configurations of a conventional LC resonator in accordance with FIG. 1.

FIG. 6A illustrates an example of a bare inductor in accordance with one of the two configurations of FIGS. 4A, 4B, 5A and 5B.

FIG. 6B illustrates an example of an inductor with a solid MIM capacitor in accordance with one of the two configurations of FIGS. 5A and 5B.

FIG. 7 illustrates an example impedance magnitude graph comparing a conventional LC resonator with a solid MIM capacitor and a LC resonator with a distributed MIM capacitor.

FIG. 8A illustrates an example of a multi-resonant series LC resonator.

FIG. 8B illustrates an example frequency response graph of three frequency response curves for the multi-resonant series LC resonator of FIG. 8A.

FIG. 9A illustrates a perspective view of an example of a parallel LC resonator.

FIG. 9B illustrates an example schematic diagram of the parallel LC resonator of FIG. 9A.

FIG. 9C illustrates an example of an impedance magnitude graph of the parallel LC resonator of FIG. 9A.

FIG. 10A shows a perspective view of an example implementation of the parallel LC resonator with a circuit input and a circuit output of FIG. 9A.

FIG. 10B illustrates an expanded perspective view of the example implementation of the parallel LC resonator with a circuit input and a circuit output shown in FIG. 10A.

FIG. 10C presents the expanded perspective view shown in FIG. 10B with additional labels added to illustrate the various constituents of the parallel LC resonator.

FIG. 11A illustrates an expanded perspective view of an example implementation of an LC resonator with capacitor grouping.

FIG. 11B illustrates an example of a schematic diagram of the LC resonator with capacitor grouping of FIG. 11A.

FIG. 12A illustrates an example of a layout of a tunable LC resonator.

FIG. 12B illustrates a schematic diagram of the tunable LC resonator of FIG. 12A.

FIG. 13 illustrates a chart of simulation results for the tunable LC resonator of FIG. 12A with the example of setting M=3.

FIG. 14 illustrates an example flow diagram X00 for implementing a scalable on-chip inductor-capacitor (LC) resonator using one or more conformally distributed capacitors.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Various aspects of the disclosure relate to systems and methods for inductor-capacitor (LC) resonator architecture. Shunt and series resonators comprised of inductors (L) and capacitors (C) (i.e., LC resonators) are main constituents in electronic systems, for example, a transceiver or power amplifier. In some examples of on-chip LC resonator implementation, the inductors may be a planar design routed on a back-end of the line (BEOL) thick metal layers. The capacitors may be on a lower thin metal layer. For example, either metal oxide semiconductor (MOS) or metal insulator metal (MIM) capacitor technologies or implementations use lower thin metal layers.

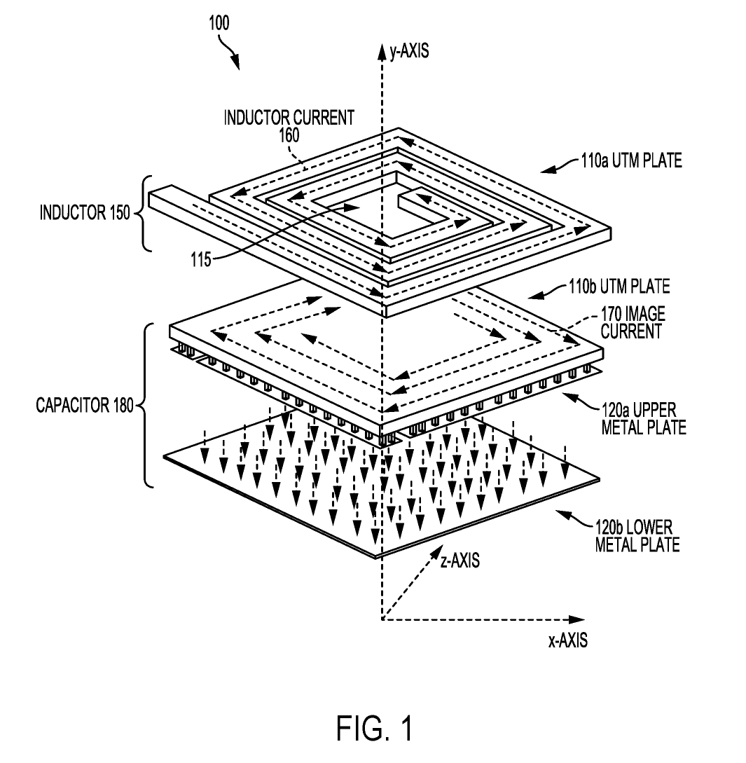

FIG. 1 illustrates a conventional inductor-capacitor (LC) resonator structure 100. In this illustration, the conventional LC resonator structure 100 includes an inductor 150 which is implemented on the top of the LC resonator structure 100. The inductor 150 includes a first ultra thick metal (UTM) 110a. The conventional LC resonator structure 100 also includes a capacitor 180 which is implemented on the bottom of the LC resonator structure 100. The capacitor 180 includes a second UTM plate 110b in combination with an upper metal plate 120a, and a lower metal plate 120b. The first UTM plate 110a has an open configuration; that is, the first UTM plate 110a includes a center hole 115. However, the second UTM plate 110b, the upper metal plate 120a and the lower metal plate 120b are all closed configurations. Closed configuration means the plates (e.g., upper metal plate 120a and/or lower metal plate 120b) are without holes. That is, none of the second UTM plate 110b, the upper metal plate 120a nor the lower metal plate 120b include a hole (such as a center hole). Each of the second UTM plate 110b, the upper metal plate 120a and the lower metal plate 120b are solid pieces without a center hole.

As shown in FIG. 1, the area occupied by the inductor 150 and the area occupied by capacitor 180 overlap with each other when viewed from a vertical direction (y-axis); that is, the inductor 150 and the capacitor 180 occupy the same space that radially expand around the y-axis in the planes of the x-axis and z-axis.

In the LC resonator structure 100, the image current 170 on the second UTM plate 110b is directed in a clockwise direction, opposite to the inductor current 160 on the first UTM plate 110a which is directed in a counter-clockwise direction. With the image current 170 flowing in the opposite direction as the inductor current 160, the total magnetic current may be significantly reduced and the inductance value may also be reduced. In the LC resonator structure 100, the total magnetic current may be a superposition of the inductor current and the image current.

The Q factor of an inductor-capacitor (LC) resonator is defined as the ratio of the resonator's stored energy to its energy loss. When the total magnetic field from the image current destructively interferes with the inductor current, there is significant de-Qing of the resonator. De-Qing is defined as the decrease in the ratio of the LC resonator's stored energy to its energy loss or energy dissipation. De-Qing may also be known as a resonator quality factor (Q factor) degradation. That is, the resonator Q factor degradation means that the Q factor of the resonator is reduced.

Since the conventional inductor-capacitor (LC) resonator structure 100 of FIG. 1 causes reduction in the total magnetic current and the inductance value, the LC resonator structure 100 results in significant de-Qing. That is, the opposite flow directions of the image current 170 and the inductor current 160 degrade the Q factor of the LC resonator structure 100 of FIG. 1.

The present disclosure relates to a scalable on-chip inductor-capacitor (LC) resonator using conformally distributed capacitors. The scalable on-chip inductor-capacitor (LC) resonator using conformally distributed capacitors architecture allows design optimization with respect to total magnetic current, inductance value and resonator size. In one aspect, a conformally distributed capacitor means that the capacitor has a shape which covers the same area as the shape of the inductor in the LC resonator.

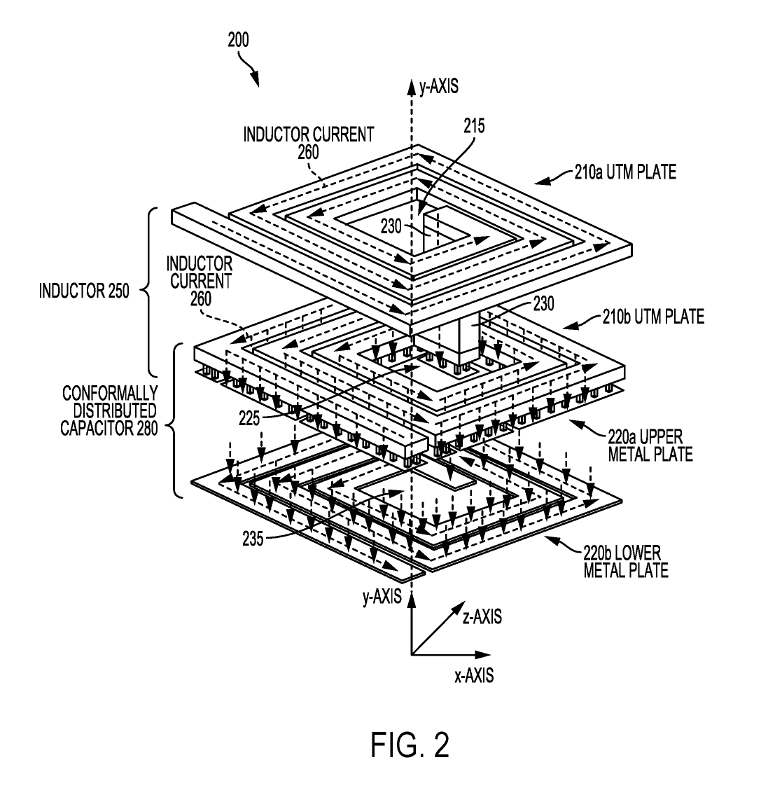

FIG. 2 illustrates an example inductor-capacitor (LC) resonator architecture 200 in accordance with the present disclosure. As shown in FIG. 2, an inductor 250 is implemented on the top portion of the LC resonator architecture 200. In one example, the inductor 250 includes a first ultra thick metal (UTM) plate 210a, an electrical coupling 230 and a second UTM plate 210b. In one example, the electrical coupling 230 is a metal piece or a via. The electrical coupling 230 couples the first UTM plate 210a with the second UTM plate 210b electrically. That is, the electrical coupling 230 provides an electrical path for the inductor current 260 to flow from the first UTM plate 210a through the electrical coupling 230 onto the second UTM plate 210b. And, as shown in FIG. 2, the inductor current 260 flows in a counter-clockwise direction on both the first UTM plate 210a and the second UTM plate 210b. One skilled in the art would understand that having the inductor current 260 flow in a clockwise direction on both the first UTM plate 210a and the second UTM plate 210b is also within the spirit and scope of the present disclosure. In another example, the inductor 250 may extend to include the upper metal plate 220a. In this example, the upper metal plate 220a is a contiguous extension of the second UTM plate 210b.

Each of the planar layers (i.e., first UTM plate 210a, second UTM plate 210b, upper metal plate 220a, lower metal plate 220b) have open configurations. Open configuration means that each of the planar layers include a hole, for example, a hole in its center (i.e., a center hole). As shown in FIG. 2, the electrical coupling 230 is situated within the center hole 215 of the first UTM plate 210a and the center hole 225 of the second UTM plate 210b. In the example shown in FIG. 2, the upper metal plate 220a shares the center hole 225 with the second UTM plate 210b. That is, both the second UTM plate 210b and the upper metal plate 220a have the same shaped cut out to form the center hole 225. In the example of FIG. 2, the lower metal plate 220b also includes a center hole 235. In one aspect, all three center holes 215, 225, 235 are similarly shaped. And, the three center holes 215, 225, 235 are vertically aligned with each other in the y-axis direction.

As shown in FIG. 2, a capacitor 280 is implemented on the bottom portion of the LC resonator architecture 200. In one example, the capacitor 280 is a conformally distributed capacitor. That is, the capacitor 280 is conformally distributed since it substantially matches the shape of the inductor 250. The capacitor 280 may be implemented with metal oxide semiconductor (MOS) layers or metal insulator metal (MIM) layers. In one example, the capacitor 280 includes the second UTM plate 210b (which may or may not include the upper metal plate 220a) and the lower metal plate 220b.

In one example, the capacitor 280 includes a width that is equal to or less than a bottom metal routing of the inductor 250. In another example, the capacitor 280 includes a planar dimension (e.g., width times length) that is equal to or less than the planar dimension (e.g., width times length) of a bottom metal routing of the inductor 250. In one example, the bottom metal routing of the inductor 250 is the second UTM plate 210b or a combination of the second UTM plate 210b with the upper metal plate 220a. The bottom metal routing of the inductor 250 may be tapped to the capacitor 280. The LC resonator architecture 200 may be implemented as either a series or a parallel (i.e., shunt) LC resonator.

In one aspect, the LC resonator architecture 200 minimizes or prevents image current from flowing on the capacitor plate since the capacitor plate is part of the inductor metal routing. The capacitor plate is either the second UTM plate 210b or the second UTM plate 210b in combination with the upper metal plate 220a. In the LC resonator architecture 200, the electrical coupling 230 allows the inductor current 260 to continuously flow from the first UTM plate 210a through to the second UTM plate 210b in the same counter-clockwise direction. This continuous flow of current in the same counter-clockwise direction substantially minimizes or prevents image current. Without the presence of image current, there is no destructive interference with the inductor current, and hence, there is no significant de-Qing of the LC resonator. Any reduction of the total magnetic current or any reduction of the inductance value are eliminated. In the LC resonator architecture 200, the total magnetic current may be the inductor current since there is no image current.

In the LC resonator architecture 200, the Q factor is preserved even though the LC resonator architecture is implemented with spatial overlap between a capacitor 280 and an inductor 250. Thus, the size requirement of the LC resonator architecture 200 is efficiently preserved while at the same time preserving its Q factor.

Although FIG. 2 shows the planar shape of the LC resonator architecture to be a square, other configurations may include, but are not limited to, circular, elliptical, rectangular, octagonal, figure-eight, any polygonal shape, etc. As shown in FIG. 2, examples of the LC resonator architecture 200 may include a variety of planarly shaped plates that are vertically stacked (i.e., in the y-axis). In various aspects, the LC resonator architecture 200 may be applied to a variety of applications, including (but not limited to): compact series or parallel LC resonators, compact multi-resonant LC resonator using a vertically stacked inductor, coupled resonators using transformers, etc. One skilled in the art would understand that the listed applications are examples and are not exclusive. Within the spirit and scope of the present disclosure, other applications may also implement the example LC resonator architecture disclosed herein.

In one aspect, the.LC resonator architecture 200 may include four layers: a first layer which is part of the inductor 250, a second layer which is shared with the inductor 250 and the capacitor 280, a third layer which is shared with the inductor 250 and the capacitor 250, and a fourth layer which is part of the capacitor 280. In one example, the first layer is the first UTM plate 210a, the second layer is the second UTM plate 210b, the third layer is the upper metal plate 220a and the fourth layer is the lower metal plate 220b. In another aspect, the LC resonator architecture 200 includes three layers: the first layer, the second layer and the fourth layer as described above. In this aspect, there is no third layer.

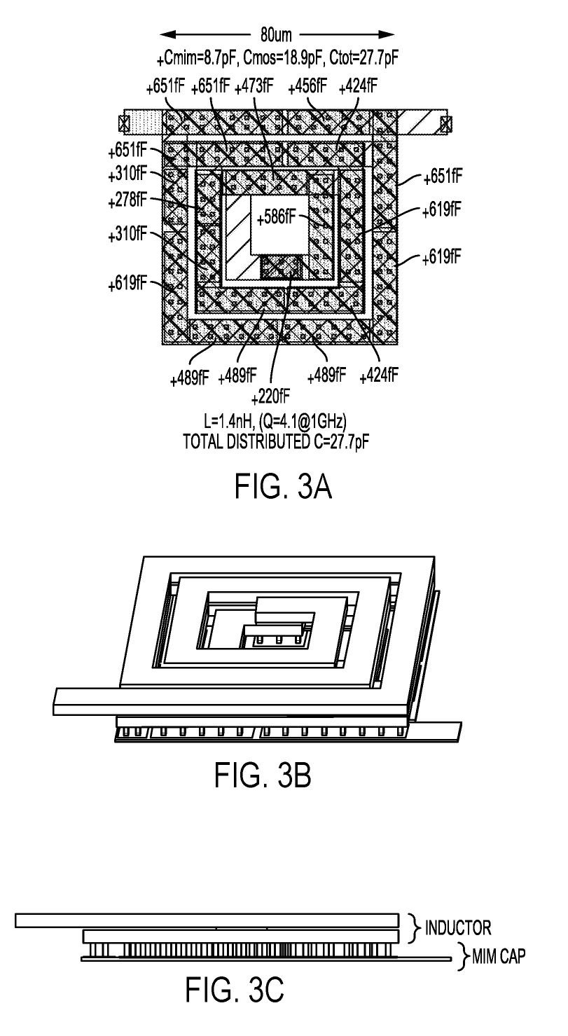

FIG. 3A illustrates an example design layout for implementing an inductor capacitor (LC) resonator in a silicon on insulator (SOI) technology. For example, an inductance L of 1.4 nanohenrys (nH) and a total capacitance C of 27.7 picofarads (pF) may be obtained with a Q factor of 4.1 at 1 GHz frequency. In this example, a top plate of the capacitor may be used to form the inductor. In addition, negative metal oxide semiconductor (NMOS) capacitors may be buried underneath metal insulator metal (MIM) capacitors. In one example, the LC resonator may be implemented in a square area of 80 micrometers by 80 micrometers. In another example, the square area may be either greater than or less than 80 micrometers by 80 micrometers. FIG. 3B illustrates a perspective view of an example electromagnetic model (e.g., high frequency structural simulator (HFSS) modeling) of the example design layout of FIG. 3A. FIG. 3C illustrates a side view of the example electromagnetic model of FIG. 3B.

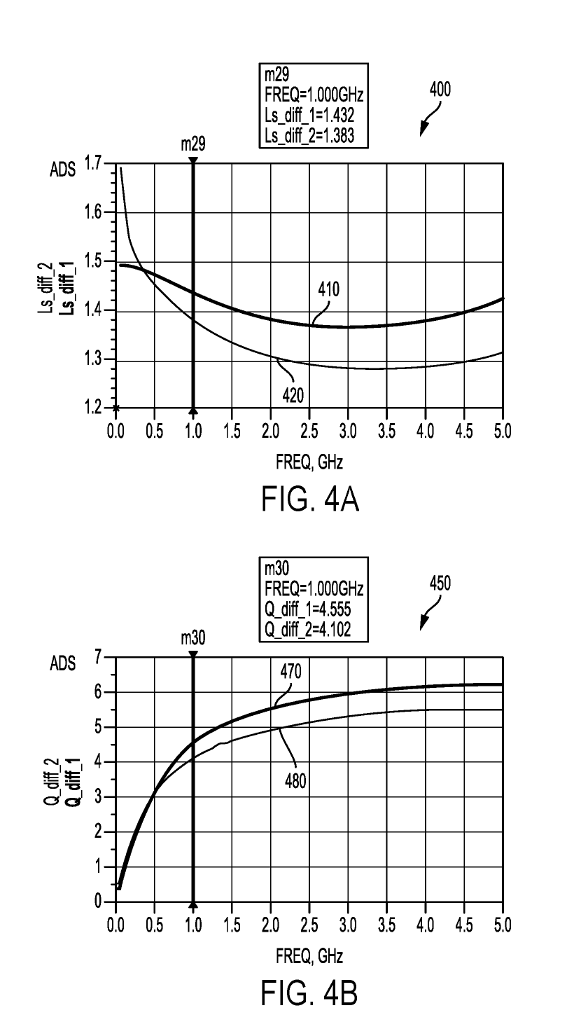

FIG. 4A illustrates an example inductance graph 400 for two configurations in accordance with an example LC resonator of the present disclosure. In FIG. 4A, the vertical axis represents inductance L in units of nanohenrys (nH) and the horizontal axis represents frequency in units of gigahertz (GHz). FIG. 4A shows a first graph 410 wherein the LC resonator implements a bare inductor. FIG. 4A also shows a second graph 420 wherein the LC resonator implements an inductor with a distributed metal insulator metal (MIM) capacitor. As shown in FIG. 4A, there is about a 5% reduction in inductance L measured at frequency 1.0 GHz in the LC resonator which implements the inductor with the distributed MIM capacitor. In one aspect, a distributed capacitor (e.g., a distributed MIM capacitor) means that the capacitor has a shape which covers an area comparable in size to the shape of the inductor in the LC resonator. The term comparable is defined as “same as” or “approximately the same as”.

One skilled in the art would understand that the graphs presented in FIG. 4A are based on example characteristics assigned to the example LC resonator, and thus, the reduction value and the characteristics of the graphs presented herein are only examples and should not be considered as limiting. Within the spirit and scope of the present disclosure, other characteristics may be assigned to the LC resonator which may change the graphs and values presented herein.

FIG. 4B illustrates an example quality factor graph 450 for two configurations in accordance with an example LC resonator of the present disclosure. In FIG. 4A, the vertical axis represents quality factor (Q factor) in dimensionless units and the horizontal axis represents frequency in units of gigahertz (GHz). FIG. 4B shows a first graph 470 wherein the LC resonator implements a bare inductor. FIG. 4B also shows a second graph 480 wherein the LC resonator implements an inductor with a distributed metal insulator metal (MIM) capacitor. As shown in FIG. 4B, there is about a 10% reduction in quality factor (Q factor) measured at frequency 1.0 GHz in the LC resonator which implements the inductor with the distributed MIM capacitor. One skilled in the art would understand that the graphs presented in FIG. 4B are based on example characteristics assigned to the example LC resonator, and thus, the reduction value and the characteristics of the graphs presented herein are only examples and should not be considered as limiting. Within the spirit and scope of the present disclosure, other characteristics may be assigned to the LC resonator which may change the graphs and values presented herein.

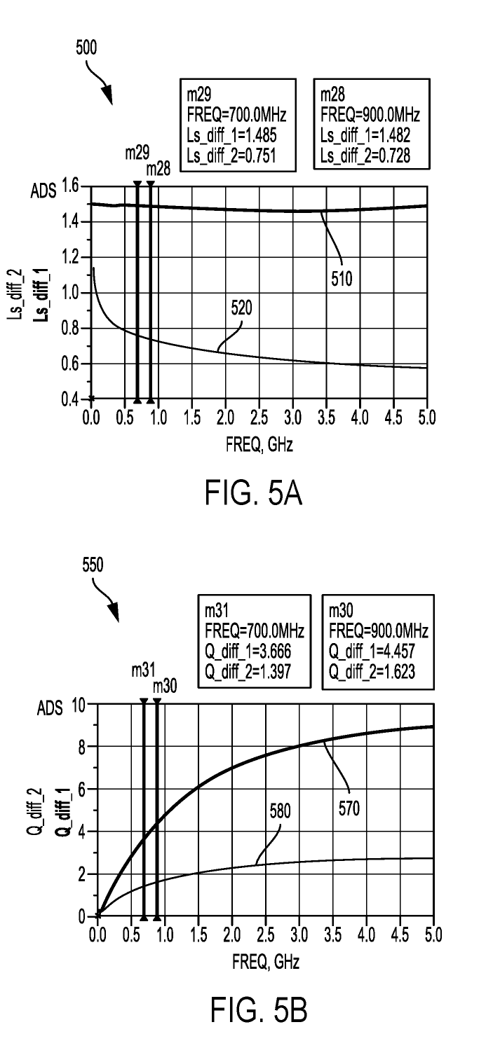

FIG. 5A illustrates an example inductance graph 500 for two configurations of a conventional LC resonator in accordance with FIG. 1. In FIG. 5A, the vertical axis represents inductance L in units of nanohenrys (nH) and the horizontal axis represents frequency in units of gigahertz (GHz). FIG. 5A shows a first graph 510 wherein the conventional LC resonator implements a bare inductor. FIG. 5A also shows a second graph 520 wherein the conventional LC resonator implements an inductor with a solid metal insulator metal (MIM) capacitor. As shown in FIG. 5A, there is about a 49.4% reduction at 700 MHz and about a 50.9% reduction at 900 MHz in inductance L in the conventional LC resonator which implements the inductor with the solid MIM capacitor. As shown in FIG. 5A, a solid MIM capacitor means that the plate of the capacitor is in a closed configuration with no hole. One skilled in the art would understand that the graphs presented in FIG. 5A are based on example characteristics assigned to the conventional LC resonator, and thus, the reduction value and the characteristics of the graphs presented herein are only examples and should not be considered as limiting. Within the spirit and scope of the present disclosure, other characteristics may be assigned to the conventional LC resonator which may change the graphs and values presented herein.

FIG. 5B illustrates an example quality factor graph 550 for two configurations of a conventional LC resonator in accordance with FIG. 1. In FIG. 5B, the vertical axis represents quality factor (Q factor) in dimensionless units and the horizontal axis represents frequency in units of gigahertz (GHz). FIG. 5B shows a first graph 570 wherein the conventional LC resonator implements a bare inductor. FIG. 5B also shows a second graph 580 wherein the conventional LC resonator implements an inductor with a solid metal insulator metal (MIM) capacitor. As shown in FIG. 5B, there is about a 61.9% reduction at 700 MHz and about a 63.6% reduction at 900 MHz in quality factor (Q factor) in the conventional LC resonator which implements the inductor with the solid MIM capacitor. As shown in FIG. 5B, a solid MIM capacitor means that the plate of the capacitor is in a closed configuration with no hole. One skilled in the art would understand that the graphs presented in FIG. 5B are based on example characteristics assigned to the conventional LC resonator, and thus, the reduction value and the characteristics of the graphs presented herein are only examples and should not be considered as limiting. Within the spirit and scope of the present disclosure, other characteristics may be assigned to the conventional LC resonator which may change the graphs and values presented herein.

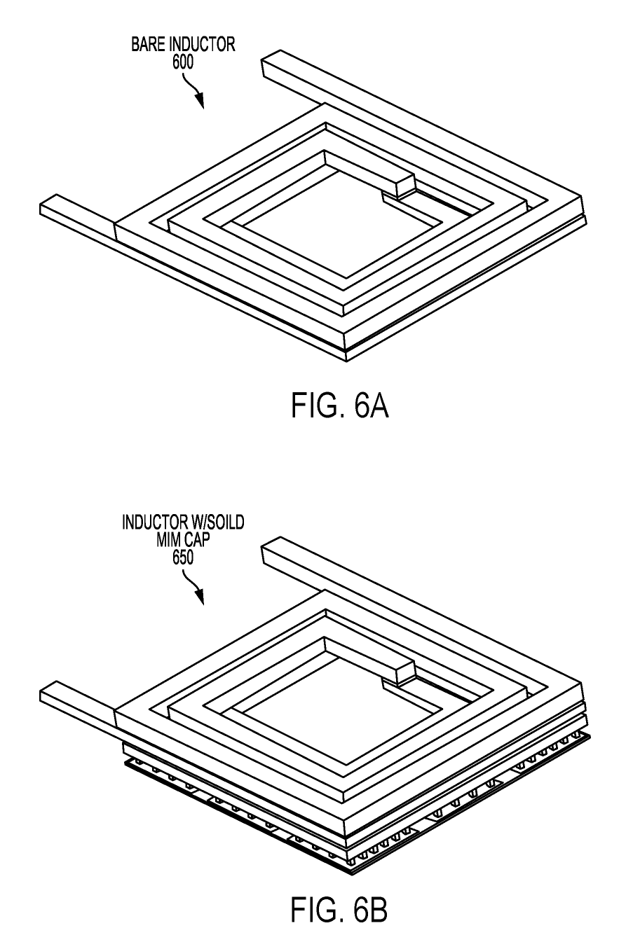

FIG. 6A illustrates an example of a bare inductor 600 in accordance with one of the two configurations of FIGS. 4A, 4B, 5A and 5B. FIG. 6B illustrates an example of an inductor with a solid MIM capacitor 650 in accordance with one of the two configurations of FIGS. 5A and 5B.

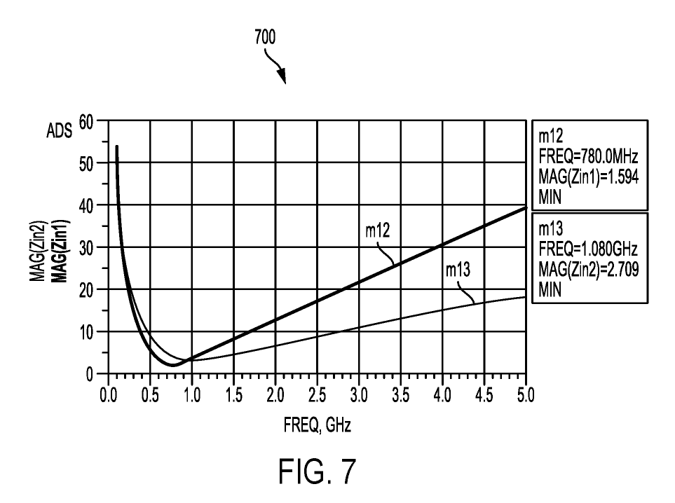

FIG. 7 illustrates an example impedance magnitude graph 700 comparing a conventional LC resonator with a solid MIM capacitor and a LC resonator with a distributed MIM capacitor. In FIG. 7, the vertical axis represents impedance magnitude (Mag(Zin)) in units of ohms and the horizontal axis represents frequency in units of gigahertz (GHz). The LC resonator with the distributed MIM capacitor is a 780 MHz series LC resonator in an area of 80 micrometers by 80 micrometers. It has a relative bandwidth of 25%. The conventional LC resonator with the solid MIM capacitor is a 1.08 GHz series LC resonator in a comparable area and has a relative bandwidth of 63%. As shown in FIG. 7, the LC resonator with the distributed MIM capacitor has a narrower relative bandwidth, and thus, a higher quality factor. One skilled in the art would understand that the graphs presented in FIG. 7 are based on example characteristics assigned to the LC resonators, and thus, the values and the characteristics of the graphs presented herein are only examples and should not be considered as limiting. Within the spirit and scope of the present disclosure, other characteristics may be assigned to the LC resonators which may change the graphs and values presented herein.

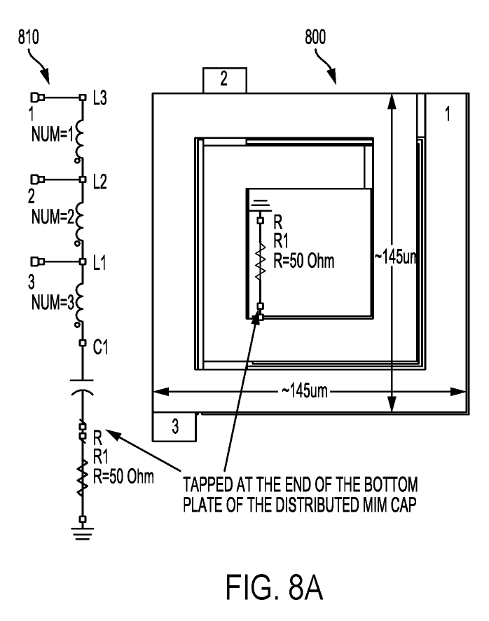

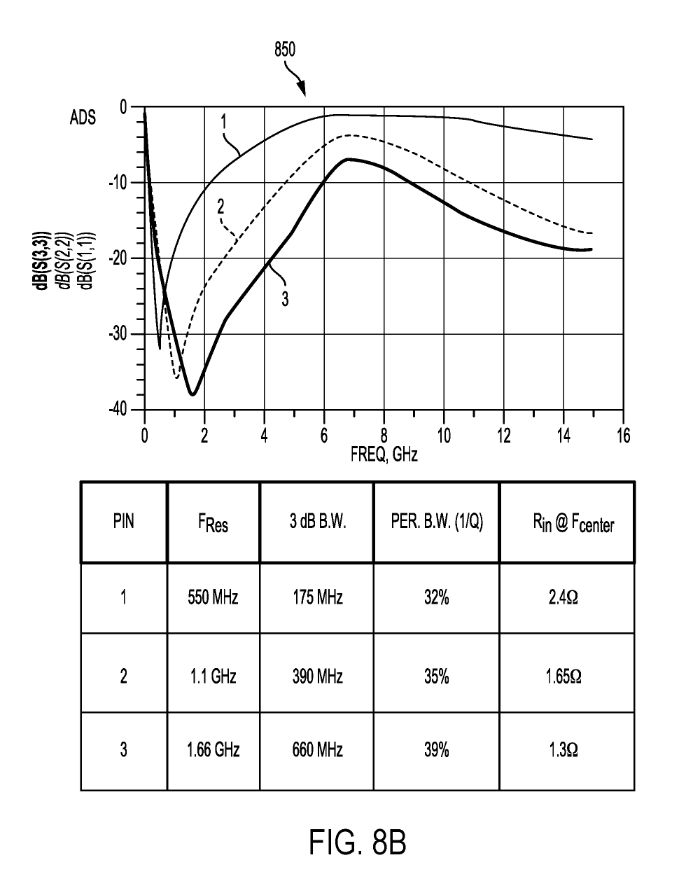

In one aspect, the LC resonator architecture of the present disclosure may include a multiple resonant series LC resonator. FIG. 8A illustrates an example of a multi-resonant series LC resonator 800. For the present disclosure, the term “multi-resonant” is synonymous with the term “multi-tapped” when describing an LC resonator. The example multi-resonant series LC resonator 800 includes three resonators and occupy an area of 145 micrometers by 145 micrometers. One skilled in the art would understand that the area of 145 micrometers by 145 micrometers is an example and does not preclude other area dimensions for a multi-resonant series LC resonator in accordance with the present disclosure. Also, one skilled in the art would understand that although three resonators are disclosed in the example of FIG. 8A, other quantities of resonators are also within the scope and spirit of the present disclosure.

In the example of FIG. 8A, a resistor R1, for example with 50 ohms, is tapped at an end of a bottom plate of a distributed MIM capacitor and terminated at ground. Also shown is a corresponding circuit schematic diagram 810 of the multi-resonant series LC resonator with three inductors L1, L2, L3, one capacitor C1 and one resistor R1. As shown inn FIG. 8A, the three inductors L1, L2, L3 are electrically coupled to each other in series. Although not shown, in another example, the three inductors L1, L2, L3 are electrically coupled to each other in parallel.

FIG. 8B illustrates an example frequency response graph 850 of three frequency response curves for the multi-resonant series LC resonator of FIG. 8A. As shown in FIG. 8B, a first resonator has a center frequency of 550 MHz, a 3 dB bandwidth of 175 MHz, a relative bandwidth of 32% and a center frequency resistance of 2.4 ohms. Also shown is a second resonator with a center frequency of 1100 MHz, a 3 dB bandwidth of 390 MHz, a relative bandwidth of 35% and a center frequency resistance of 1.65 ohms. And, also shown is a third resonator with a center frequency of 1660 MHz, a 3 dB bandwidth of 660 MHz, a relative bandwidth of 39% and a center frequency resistance of 1.3 ohms. One skilled in the art would understand that the various characteristics of the three resonators shown in FIG. 8B are disclosed herein as examples, and that other characteristics (and corresponding values) are not precluded and are within the spirit and scope of the present disclosure.

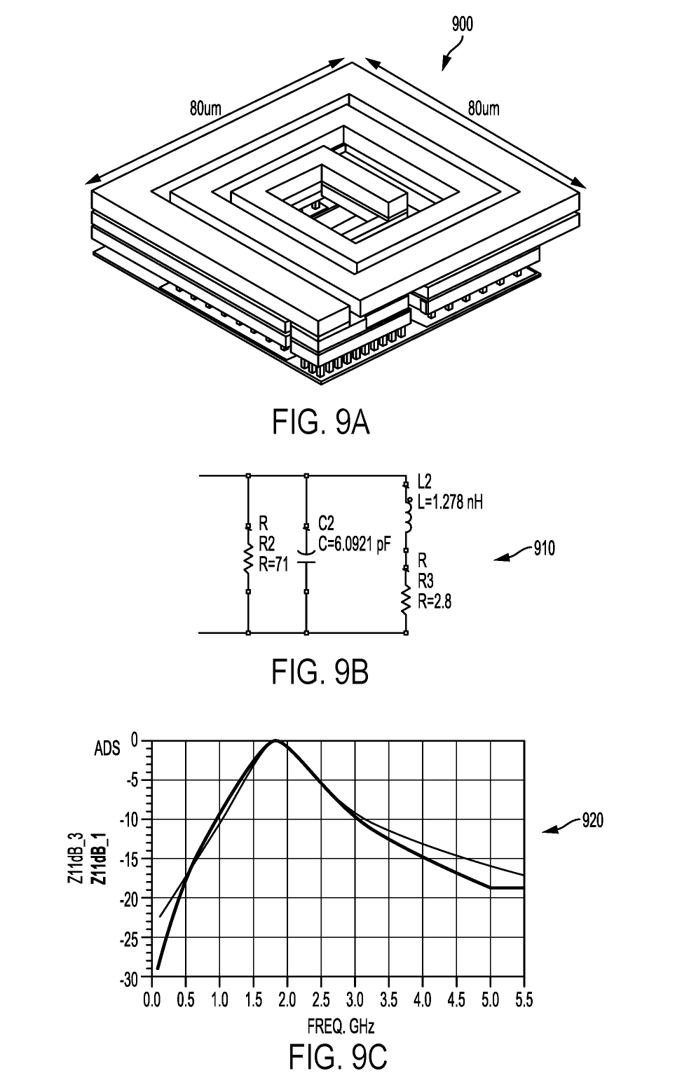

In one aspect, the LC resonator architecture of the present disclosure may include a parallel LC resonator, including a multiple resonant parallel LC resonator. FIG. 9A illustrates a perspective view of an example of a parallel LC resonator 900. In FIG. 9A, the example parallel LC resonator 900 include lateral dimensions of 80 micrometers by 80 micrometers. The parallel LC resonator 900 is implemented with an inductor on the top and a capacitor on the bottom, connected in parallel. FIG. 9B illustrates an example schematic diagram 910 of the parallel LC resonator of FIG. 9A. As shown in FIG. 9B, the parallel LC resonator has an inductance value L2 of 1.278 nanohenrys (nH), a capacitance value C2 of 6.0921 picofarads (pF), a series resistance value R3 of 2.8 ohms and a parallel resistance value R2 of 71 ohms. One skilled in the art would understand that the inductance, capacitance and resistance values shown in FIG. 9B are examples and do not preclude other values which would also be within the spirit and scope of the present disclosure.

FIG. 9C illustrates an example of an impedance magnitude graph 920 of the parallel LC resonator 900 of FIG. 9A. In FIG. 9C, the vertical axis represents the impedance magnitude in units of decibels (dB) and the horizontal axis represents frequency in units of gigahertz (GHz) frequency. The trace labeled as Z11dB_1 is the impedance of an electromagnetic (EM) model of the parallel LC resonator 900 of FIG. 9A. The trace labeled as Z11dB_3 is the impedance of the equivalent circuit 910 of FIG. 9B. In one aspect, the concurrence between the two impedance magnitude graphs (the trace labeled as Z11dB_1 and the trace labeled as Z11dB_3) in FIG. 9C confirms the parallel LC resonance functionality of the parallel LC resonator 900 of FIG. 9A. In the parallel LC resonator 900, the resonance frequency is at 1.8 GHz and the bandwidth is 750 MHz. In one example, by stacking an additional metal oxide semiconductor (MOS) capacitor in parallel with the parallel LC resonator 900, a second resonance frequency of 800 MHz may be achieved in the same area. One skilled in the art would understand that the various characteristics of the parallel LC resonator shown in FIG. 9C are disclosed herein as examples, and that other characteristics (and corresponding values) are not precluded and are within the spirit and scope of the present disclosure.

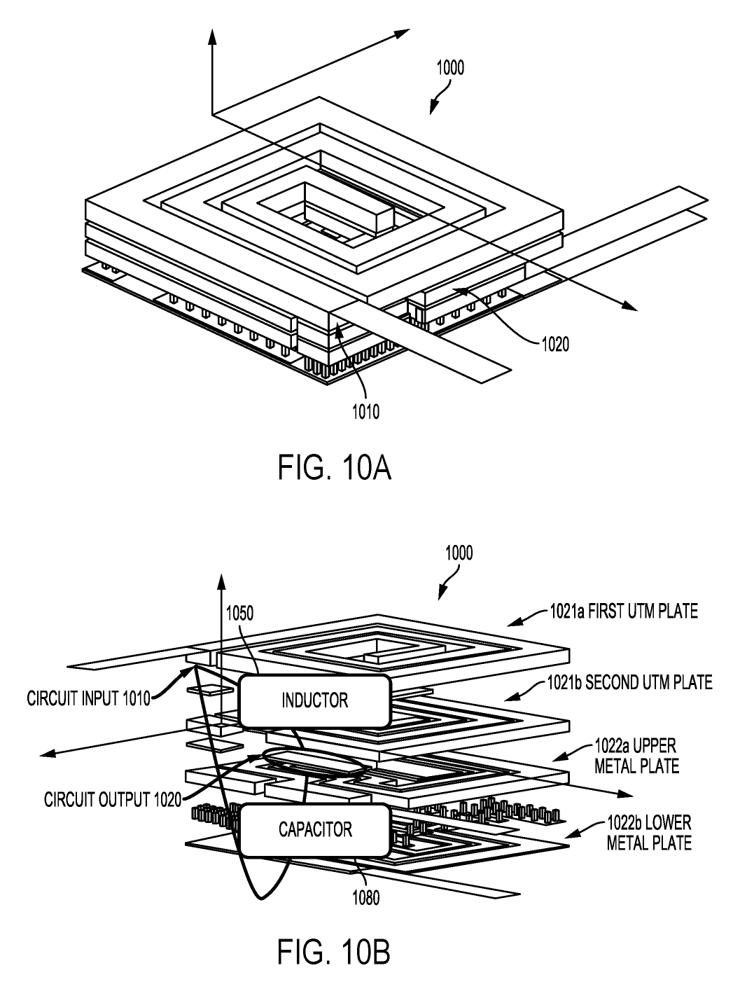

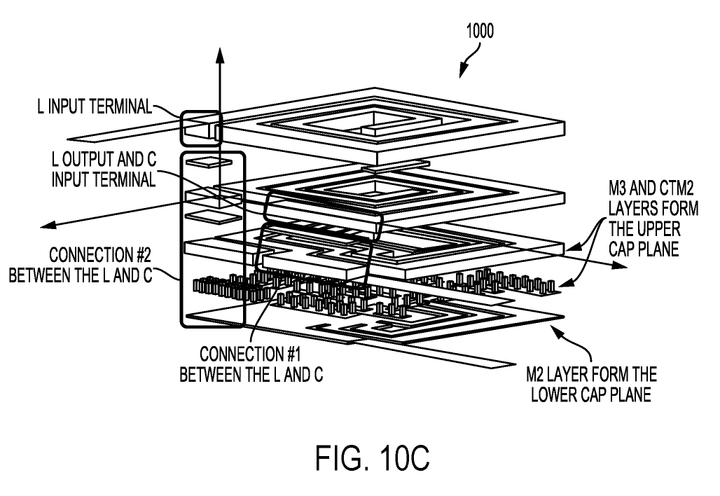

FIG. 10A shows a perspective view of an example implementation of the parallel LC resonator 1000 with a circuit input and a circuit output of FIG. 9A. As used herein, the term circuit input (a.k.a. circuit input terminal) and the term resonator input are synonymous. And, as use herein, the term circuit output (a.k.a. circuit output terminal) and the term resonator output are synonymous. In FIG. 10A, the parallel LC resonator 1000 includes a circuit input 1010 and a circuit output 1020. Although FIG. 10A shows particular positions for the circuit input 1010 and the circuit output 1020 relative to the parallel LC resonator 1000, one skilled in the art would understand that other positions on the parallel LC resonator 1000 could also accommodate the circuit input 1010 and the circuit output 1020 within the spirit and scope of the present disclosure. Although only one circuit input and one circuit output is shown in FIG. 10A, one skilled in the art would understand that in other implementations, the parallel LC resonator 1000 may accommodate multiple circuit inputs and/or multiple circuit outputs within the spirit and scope of the present disclosure.

FIG. 10B illustrates an expanded perspective view of the example implementation of the parallel LC resonator 1000 with a circuit input 1010 and a circuit output 1020 shown in FIG. 10A. As shown in FIG. 10B, an inductor 1050 is placed on a top portion of the parallel LC resonator and a capacitor 1080 is placed on a bottom portion of the parallel LC resonator. FIG. 10B. Also shown in FIG. 10B are the spatial relationships between a first UTM plate 1021a, a second UTM plate 1021b, an upper metal plate 1022a and a lower metal plate 1022b. FIG. 10B also shows the constituents of the inductor 1050 and the constituents of the capacitor 1080. For example, the constituents of the inductor 1050 may include the first UTM plate 1021a and the second UTM plate 1021b, while the constituents of the capacitor 1080 may include the upper metal plate 1022a and the lower metal plate 1022b.

FIG. 10C presents the expanded perspective view shown in FIG. 10B with additional labels added to illustrate the various constituents of the parallel LC resonator 1000. FIG. 10C shows an inductor input terminal (a.k.a., L input terminal) and an inductor output and capacitor input terminal (a.k.a. L output and C input terminal). In one example, the inductor input terminal is the circuit input 1010 shown in FIG. 10B, and the inductor output and capacitor input terminal is the circuit output 1020 shown in FIG. 10B. In the expanded perspective view, two connections (connection #1 and connection #2) between the inductor 1050 and the capacitor 1080 are shown. Note that in FIG. 10C, the inductor is labeled as “L” and the capacitor is labeled as “C”. FIG. 10C also details the constituents of the capacitor 1080 by indication that as an example, a second metal layer (M2) may function as a lower capacitor plane for the capacitor 1080. FIG. 10C also indicates that as an example, a third metal layer (M3) and an upper capacitor top metal (CTM) layer (labeled as CTM2) may function as an upper capacitor plane for the capacitor 1080.

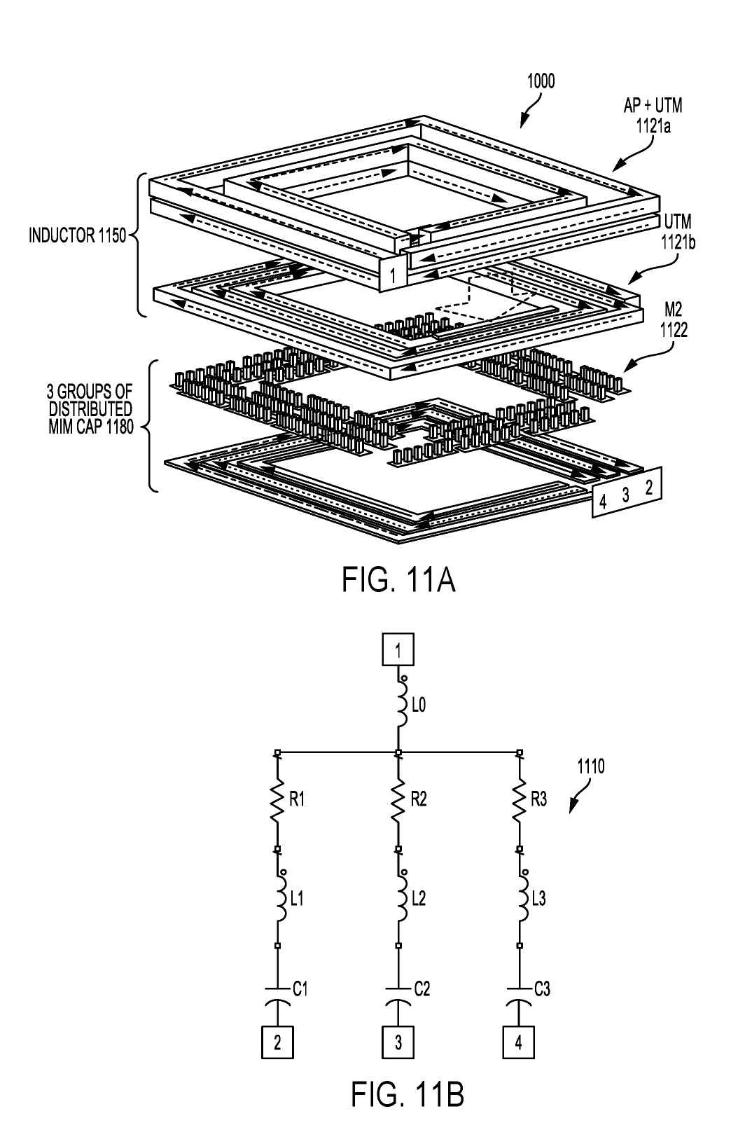

FIG. 11A illustrates an expanded perspective view of an example implementation of an LC resonator with capacitor grouping 1100. With the present disclosure, the LC resonator with capacitor grouping 1100 may also be referred to as LC resonator 1100. As shown in FIG. 11A, an inductor 1150 is on the top portion of the LC resonator 1100 and 3 groups of distributed capacitors 1180 are on the bottom portion of the LC resonator 1100. In one example, the distributed capacitors may be metal insulator metal (MIM) capacitors. And, although FIG. 11A labels the 3 groups of distributed capacitors 1180 as MIM capacitors, one skilled in the art would understand that other types of capacitors, for example but not limited to, metal oxide semiconductor (MOS) capacitors are also within the spirit and scope of the present disclosure.

Shown in FIG. 11A are two ultra thick metal (UTM) plates 1121a, 1121b, and a metal plate (M2) 1122 which make up some of the constituents of the LC resonator 1100. In one example, the UTM plate 1121a may also include an aluminum plate (AP). Alternatively, in another example, the UTM plate 1121a may also include a metal plate where the metal is not aluminum. In one example, the metal plate (M2) 1122 includes a plurality of discrete metal plates which are constituents for forming a plurality of capacitors. In one example, the plurality of capacitors may be grouped in N sets. If the plurality of capacitors are combined in equal parallel sets, the loss of the second metal plate (M2) 1122 may be reduced by a factor of N. In another aspect, if each group of the capacitors is set to a different capacitance value, a quantity of (2^{N}−1) resonances may be achievable. Shown in FIG. 11A as an example, are 3 groups of distributed capacitors 1180. However, it is understood that within the spirit and scope of the present disclosure, other quantities of groups are possible. Also, the quantity of capacitors in each group may also vary according to design and applications.

FIG. 11B illustrates an example of a schematic diagram 1110 of the LC resonator with capacitor grouping of FIG. 11A. For example, the structure in FIG. 11A has four terminations: termination 1 is the current input terminal on the top metal trace, terminations 2, 3, 4 are the current exit terminals on the bottom metal layer. In one aspect, paths 1-2, 1-3, and 1-4 experience different series LC values and therefore they experience different resonance frequencies. In the examples of FIGS. 11A and 11B, the terminals labeled 1, 2, 3, 4 in FIG. 11B correspond to the terminations labeled 1, 2, 3, 4 in FIG. 11A, respectively. The schematic diagram shows a single inductor L0 with input terminal 1 and three parallel branches. The single inductor L0 schematically corresponds to the inductor 1150 shown in FIG. 11A. The three parallel branches schematically correspond to the 3 groups of distributed capacitors 1180 shown in FIG. 11A. The three parallel branches include: a) a first branch with a first capacitor C1, a first resistor R1, a first inductor L1 and a first output terminal 2; b) a second branch with a second capacitor C2, a second resistor R2, a second inductor L2 and a second output terminal 3; and c) a third branch with a third capacitor C3, a third resistor R3, a third inductor L3 and a third output terminal 4. As shown in FIG. 11B, the first capacitor C1, the second capacitor C2 and the third capacitor C3 are electrically coupled to each other in parallel. Although not shown in FIG. 11B, in another example, the first capacitor C1, the second capacitor C2 and the third capacitor C3 may be electrically coupled to each other in series.

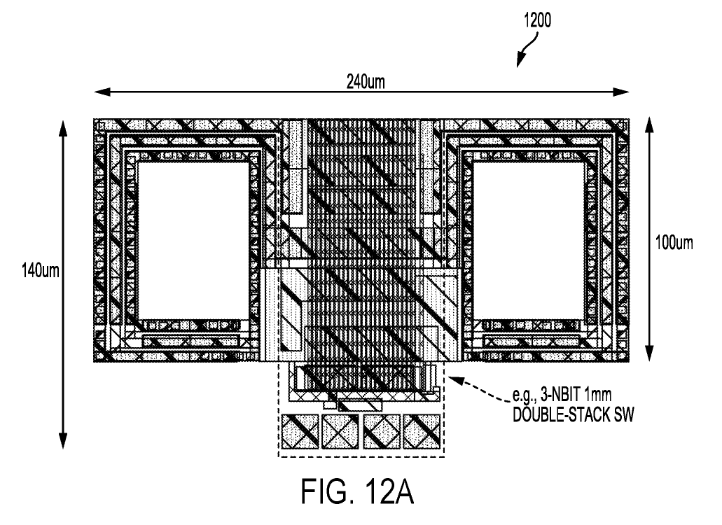

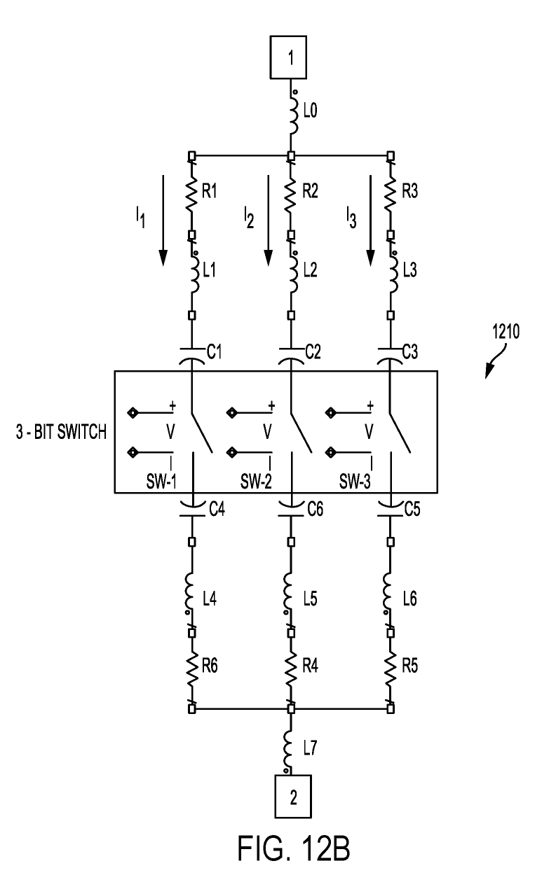

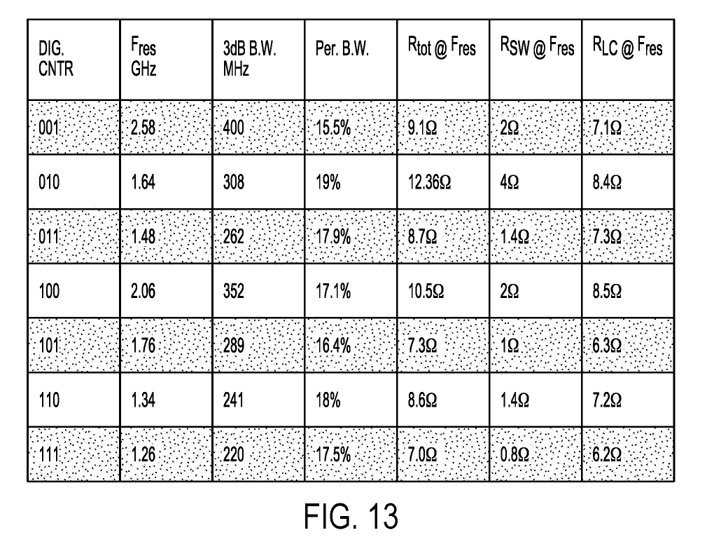

FIG. 12A illustrates an example of a layout of a tunable LC resonator 1200. In one example, the tunable LC resonator 1200 includes an M bit switch and has a first dimension of 240 micrometers and a second dimension of 140 micrometers. In one example, the second dimension comprises a vertical circuit dimension of 100 micrometers. FIG. 12B illustrates a schematic diagram 1210 of the tunable LC resonator 1200 of FIG. 12A. In one example, the M bit switch includes up to 2^{M} states. Shown in FIG. 12B as an example, the tunable LC resonator 1200 has a 3 bit switch; that is, M =3. Thus, the M bit switch of the tunable LC resonator 1200 has up to 8 states; that is 2³ states. One skilled in the art would understand that although a 3 bit switch is shown, other values of M are within the spirit and scope of the present disclosure. In one aspect, the tunable LC resonator shown in FIG. 12B is based on the design shown in FIG. 11B. In this example, two multi-resonance structures similar to the one shown in FIG. 11A are connected back-to-back through a 3 bit switch. In one example, the implementation shown in FIG. 12A is based on CMOS technology. The 3 bit switch is controlled by means of a digital signal which turns on or off SW-1, SW-2 and SW-3. In one example, SW-1 controls a first current I1 through a first path between terminals 1 and 2, SW-2 controls a second current I2 through a second path between terminals 1 and 2, and SW-3 controls a third current 13 though a third path between terminals 1 and 2. In one aspect, each current traverses a different series LC combination. A 3 bit switch offers a total of 2̂=8 parallel combinations of the series LC combination in each path. FIG. 13 lists corresponding resonance frequencies, bandwidths and resistances at resonance for the tunable LC resonator 1200 of FIG. 12A.

FIG. 13 illustrates a chart 1300 of simulation results for the tunable LC resonator 1200 of FIG. 12A with the example of setting M=3. Chart 1300 shows 7 states with a first column of digital counter states (with 3 bits), a second column of resonant frequency (in GHz), a third column of 3 dB bandwidth (in MHz), a fourth column of percent bandwidth (in %), a fifth column of total resistance Rₜₒₜ (in ohms) at the resonant frequency, a sixth column of switch resistance R_{sw} (in ohms) at the resonant frequency, and seventh column of resonant resistance R_{LC} (in ohms) at the resonant frequency. In one aspect, the percent bandwidth is obtained from the ratio of 3 dB bandwidth to resonant frequency. In another aspect, the total resistance is obtained from the sum of the switch resistance and resonant resistance. One skilled in the art would understand that the simulation results presented in FIG. 13 are examples based on particular characteristics chosen for the tunable LC resonator 1200 and do not preclude other characteristics that may be chosen for the tunable LC resonator 1200 and which may lead to other simulation results than those presented in FIG. 13.

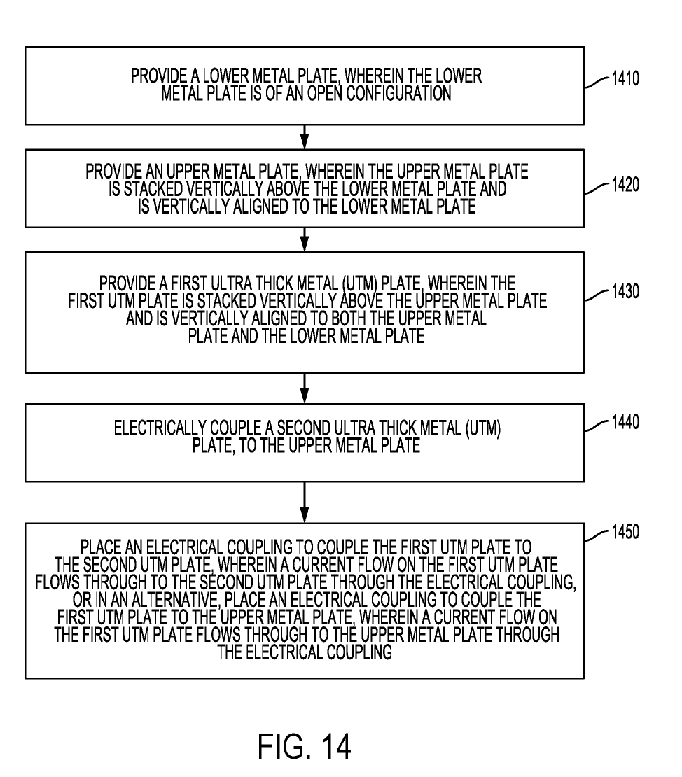

FIG. 14 illustrates an example flow diagram 1400 for implementing a scalable on-chip inductor-capacitor (LC) resonator using one or more conformally distributed capacitors. In block 1410, provide a lower metal plate, wherein the lower metal plate is of an open configuration. In one example, the lower metal plate is of a planar shape with a center hole. The planar shape of the lower metal plate may include a circular shape, an elliptical shape, a square shape, a rectangular shape, an octagonal shape, a figure eight shape or any polygonal shape. And, the center hole may be an opening of any shape, which may include a circular shape, an elliptical shape, a square shape, a rectangular shape, an octagonal shape, a figure eight shape or any polygonal shape.

In block 1420, provide an upper metal plate, wherein the upper metal plate is stacked vertically above the lower metal plate and is vertically aligned to the lower metal plate. In one example, the upper metal plate is of an open configuration. In one example, vertically aligned means that the center of a first plate and the center of a second plate define a cardinal axis (e.g., y-axis of FIG. 2) which is orthogonal to the other two cardinal axes (e.g., x-axis and z-axis of FIG. 2). Cardinal axes are a set of three dimensional Cartesian coordinates which are mutually orthogonal.

In one example, the upper metal plate is of a planar shape with a center hole. The planar shape of the upper metal plate may include a circular shape, an elliptical shape, a square shape, a rectangular shape, an octagonal shape, a figure eight shape or any polygonal shape. And, the center hole may be an opening of any shape, which may include a circular shape, an elliptical shape, a square shape, a rectangular shape, an octagonal shape, a figure eight shape or any polygonal shape. In one example, the lower metal plate includes a width that is equal to or less than a width of the upper metal plate. In another example, the lower metal plate has a planar dimension that is equal or less than the planar dimension of the upper metal plate.

In block 1430, provide a first ultra thick metal (UTM) plate, wherein the first UTM plate is stacked vertically above the upper metal plate and is vertically aligned to both the upper metal plate and the lower metal plate. In one example, the first UTM plate is of is of an open configuration. For example, the first UTM plate has a planar shape and includes a center hole. The planar shape of the first UTM plate may include a circular shape, an elliptical shape, a square shape, a rectangular shape, an octagonal shape, a figure eight shape or any polygonal shape. And, the center hole may be an opening of any shape, which may include a circular shape, an elliptical shape, a square shape, a rectangular shape, an octagonal shape, a figure eight shape or any polygonal shape. In one example, the lower metal plate includes a width that is equal to or less than a width of the first UTM plate. In another example, the lower metal plate has a planar dimension that is equal or less than the planar dimension of the first UTM plate.

In block 1440, electrically couple a second ultra thick metal (UTM) plate, to the upper metal plate. In one example, the second UTM plate is stacked vertically above the upper metal plate and is vertically aligned to both the upper metal plate and the lower metal plate. In one example, the second UTM plate is of an open configuration. For example, the second UTM plate is of a planar shape and has a center hole. The planar shape of the second UTM plate may include a circular shape, an elliptical shape, a square shape, a rectangular shape, an octagonal shape, a figure eight shape or any polygonal shape. And, the center hole may be an opening of any shape, which may include a circular shape, an elliptical shape, a square shape, a rectangular shape, an octagonal shape, a figure eight shape or any polygonal shape. In one example, the lower metal plate includes a width that is equal to or less than a width of the second UTM plate. In another example, the lower metal plate has a planar dimension that is equal or less than the planar dimension of the second UTM plate.

In one example, the center holes of each of the lower metal plate, the upper metal plate, the second UTM plate and the first UTM plate are of the same shape and dimension. In one example, each of the lower metal plate, the upper metal plate, the second UTM plate and the first UTM plate are of the same shape as each other. In one example, each of the lower metal plate, the upper metal plate, the second UTM plate and the first UTM plate are of the same dimension as each other.

In block 1450, place an electrical coupling to couple the first UTM plate to the second UTM plate, wherein a current on the first UTM plate flows through to the second UTM plate through the electrical coupling. In an alternative where the scalable on-chip inductor-capacitor (LC) resonator does not include a second UTM plate, place an electrical coupling to couple the first UTM plate to the upper metal plate, wherein a current on the first UTM plate flows through to the upper metal plate through the electrical coupling. In one example, the current flows in a counter-clockwise direction on the first UTM plate and in the same counter-clockwise direction on the second UTM plate. In another example, the current flows in a clockwise direction on the first UTM plate and in the same clockwise direction on the second UTM plate. Also, in an alternative example, the current flows in a counter-clockwise direction on the first UTM plate and in the same counter-clockwise direction on the upper metal plate. In another example, the current flows in a clockwise direction on the first UTM plate and in the same clockwise direction on the upper metal plate. In one example the electrical coupling is placed in the center hole of the first UTM plate. In one example, the electrical coupling is a piece of metal or a via.

In one example, an inductor is formed by the first UTM plate and the second UTM plate, or by the first UTM plate and a combination of the second UTM plate and the upper metal plate. In an alternative example, where the scalable on-chip inductor-capacitor (LC) resonator does not include a second UTM plate, inductor is formed by the first UTM plate and the upper metal plate.

In one example, a capacitor is formed by the lower metal plate and the second UTM plate, or by the lower metal plate and a combination of the second UTM plate and the upper metal plate. In an alternative example, where the scalable on-chip inductor-capacitor (LC) resonator does not include a second UTM plate, capacitor is formed by the lower metal plate and the upper metal plate.

In one aspect, the inductor and the capacitor are electrically coupled to each other in a series configuration. In another aspect, the inductor and the capacitor are electrically coupled to each other in a parallel configuration. In one aspect, the first UTM plate includes a plurality of UTM plates to form a plurality of inductors. In one example, the plurality of inductors and the capacitor are in a series configuration. In another example, the plurality of the inductors and the capacitor are in a parallel configuration.

In one aspect, one or more of the steps for providing a UTM plate or a metal plate in FIG. 14 may be executed by one or more processors which may include hardware, software, firmware, etc. In one aspect, one or more of the steps for electrical coupling UTM plate(s) and/or metal plate(s) in FIG. 14 may be executed by one or more processors which may include hardware, software, firmware, etc. The one or more processors, for example, may be used to execute software or firmware needed to perform the steps in the flow diagram of FIG. 14. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in the processing system, external to the processing system, or distributed across multiple entities including the processing system. The computer-readable medium may be embodied in a computer program product. By way of example, a computer program product may include a computer-readable medium in packaging materials. The computer-readable medium may include software or firmware for placement and routing of the PG cells to the cell building blocks of the power grid (PG) architecture. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. An inductor-capacitor (LC) resonator architecture, comprising:
a lower metal plate, wherein the lower metal plate is of an open configuration;
an upper metal plate, wherein the upper metal plate is stacked vertically above the lower metal plate and is vertically aligned to the lower metal plate;
a first ultra thick metal (UTM) plate, wherein the first UTM plate is stacked vertically above the upper metal plate and is vertically aligned to both the upper metal plate and the lower metal plate; and
an electrical coupling to couple the first UTM plate to the upper metal plate, wherein a current on the first UTM plate flows through to the upper metal plate through the electrical coupling, the current flows in a direction on the first UTM plate and in the same direction on the upper metal plate.

2. The inductor-capacitor (LC) resonator architecture of claim 1, further comprising a second ultra thick metal (UTM) plate, the second UTM plate electrically coupled to the upper metal plate.

3. The inductor-capacitor (LC) resonator architecture of claim 2, further comprising a circuit input terminal, wherein the circuit input terminal is electrically coupled to the first UTM plate.

4. The inductor-capacitor (LC) resonator architecture of claim 3, further comprising a circuit output terminal, wherein the circuit output terminal is electrically coupled to one or more of the following: the second UTM plate or the upper metal plate.

5. The inductor-capacitor (LC) resonator architecture of claim 1, wherein the lower metal plate has a first planar shape and the open configuration is a first center hole on the first planar shape.

6. The inductor-capacitor (LC) resonator architecture of claim 5, wherein the upper metal plate has a second planar shape and the second planar shape has a second center hole.

7. The inductor-capacitor (LC) resonator architecture of claim 6, wherein the first UTM plate has a third planar shape and the third planar shape has a third center hole.

8. The inductor-capacitor (LC) resonator architecture of claim 7, wherein the first center hole, the second center hole and the third center hole are of the same shape and are each vertically aligned to one another along an axis.

9. The inductor-capacitor (LC) resonator architecture of claim 1, wherein the electrical coupling is a via.

10. The inductor-capacitor (LC) resonator architecture of claim 1, wherein the first UTM plate and the upper metal plate are constituents of an inductor.

11. The inductor-capacitor (LC) resonator architecture of claim 10, wherein the lower metal plate and the upper metal plate are constituents of a capacitor.

12. The inductor-capacitor (LC) resonator architecture of claim 11, wherein the inductor and the capacitor are electrically coupled in series.

13. The inductor-capacitor (LC) resonator architecture of claim 11, wherein the inductor and the capacitor are electrically coupled in parallel.

14. The inductor-capacitor (LC) resonator architecture of claim 11, wherein the capacitor is either a metal oxide semiconductor (MOS) capacitor or a metal insulator metal (MIM) capacitor.

15. The inductor-capacitor (LC) resonator architecture of claim 1, wherein the first ultra thick metal (UTM) plate includes a plurality of metal plates, the plurality of metal plates being constituents for at least two or more inductors.

16. The inductor-capacitor (LC) resonator architecture of claim 15, wherein the at least two or more inductors are electrically coupled in parallel.

17. The inductor-capacitor (LC) resonator architecture of claim 15, wherein the at least two or more inductors are electrically coupled in series.

18. The inductor-capacitor (LC) resonator architecture of claim 1, wherein the lower metal plate includes a plurality of discrete metal plates, the plurality of discrete metal plates being constituents for at least two or more capacitors.

19. The inductor-capacitor (LC) resonator architecture of claim 18, wherein the at least two or more capacitors are electrically coupled in parallel.

20. The inductor-capacitor (LC) resonator architecture of claim 18, wherein the at least two or more capacitors are electrically coupled in series.

21. A method for implementing a scalable on-chip inductor-capacitor (LC) resonator using one or more conformally distributed capacitors comprising:
providing a lower metal plate, wherein the lower metal plate is of an open configuration;
providing an upper metal plate, wherein the upper metal plate is stacked vertically above the lower metal plate and is vertically aligned to the lower metal plate;
providing a first ultra thick metal (UTM) plate, wherein the first UTM plate is stacked vertically above the upper metal plate and is vertically aligned to both the upper metal plate and the lower metal plate; and
placing an electrical coupling to couple the first UTM plate to the upper metal plate, wherein a current on the first UTM plate flows through to the upper metal plate through the electrical coupling, the current flows in a direction on the first UTM plate and in the same direction on the upper metal plate.

22. The method of claim 21, further comprising electrically coupling a second ultra thick metal (UTM) plate to the upper metal plate.

23. The method of claim 21, wherein the lower metal plate has a first planar shape and further comprising implementing a first center hole on the first planar shape.

24. The method of claim 23, wherein the upper metal plate has a second planar shape and further comprising implementing a second center hole on the second planar shape.

25. The method of claim 24, wherein the first UTM plate has a third planar shape and further comprising implementing a third center hole on the third planar shape.

26. The method of claim 25, further comprising vertically aligning the first center hole, the second center hole and the third center hole to each other along an axis.

27. An apparatus for implementing a scalable on-chip inductor-capacitor (LC) resonator using one or more conformally distributed capacitors, the apparatus comprising:
means for providing a lower metal plate, wherein the lower metal plate is of an open configuration;
means for providing an upper metal plate, wherein the upper metal plate is stacked vertically above the lower metal plate and is vertically aligned to the lower metal plate;
means for providing a first ultra thick metal (UTM) plate, wherein the first UTM plate is stacked vertically above the upper metal plate and is vertically aligned to both the upper metal plate and the lower metal plate; and
means for placing an electrical coupling to couple the first UTM plate to the upper metal plate, wherein a current on the first UTM plate flows through to the upper metal plate through the electrical coupling, the current flows in a direction on the first UTM plate and in the same direction on the upper metal plate.

28. The apparatus of claim 27, further comprising means for electrically coupling a second ultra thick metal (UTM) plate to the upper metal plate.

29. A computer-readable medium storing computer executable code, operable on a device comprising at least one processor and at least one memory coupled to the at least one processor, wherein the at least one processor is configured to implement a scalable on-chip inductor-capacitor (LC) resonator using one or more conformally distributed capacitors, the computer executable code comprising:
instructions for causing a computer to provide a lower metal plate, wherein the lower metal plate is of an open configuration;
instructions for causing the computer to provide an upper metal plate, wherein the upper metal plate is stacked vertically above the lower metal plate and is vertically aligned to the lower metal plate;
instructions for causing the computer to provide a first ultra thick metal (UTM) plate, wherein the first UTM plate is stacked vertically above the upper metal plate and is vertically aligned to both the upper metal plate and the lower metal plate; and
instructions for causing the computer to place an electrical coupling to couple the first UTM plate to the upper metal plate, wherein a current on the first UTM plate flows through to the upper metal plate through the electrical coupling, the current flows in a direction on the first UTM plate and in the same direction on the upper metal plate.

30. The computer-readable medium of claim 30, further comprising instructions for causing the computer to electrically couple a second ultra thick metal (UTM) plate to the upper metal plate.
